(19) United States
(12) Patent Application Publication
(10) Pub. No.: US 2010/0213534 A1
(43) Pub. Date: Aug. 26, 2010

(54) NONVOLATILE SEMICONDUCTOR MEMORY DEVICE AND MANUFACTURING METHOD FOR THE SAME

(76) Inventors: Katsuyuki SEKINE, Kanagawa-ken (JP); Katsuaki Natori, Kanagawa-ken (JP); Tetsuya Kai, Kanagawa-ken (JP); Yoshio Ozawa, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/709,154

(22) Filed: Feb. 19, 2010

(30) Foreign Application Priority Data
Feb. 20, 2009 (JP) P2009-038642

(51) Int. Cl. H01L 29/788; H01L 21/28

(52) U.S. Cl. 257/321; 438/594; 257/E29.3; 257/E21.209

(57) ABSTRACT

In a nonvolatile semiconductor memory device provided with memory cell transistors, each of the memory cell transistors has a tunnel insulating film, a floating gate electrode, an inter-electrode insulating film, and element isolation insulating films respectively. The floating gate electrode on the tunnel insulating film is provided with a first floating gate electrode and a second floating gate electrode formed sequentially from the bottom, the second floating gate electrode being narrower in a channel-width direction than the first one. Levels of upper surfaces of the element isolation insulating films and the first floating gate electrode are the same. The inter-electrode insulating film continuously covers the upper and side surfaces of the floating gate electrode and the upper surfaces of the element isolation insulating films, and is higher in a nitrogen concentration in a boundary portion to the floating gate electrode than in boundary portions to the element isolation insulating films.

### CROSS REFERENCE TO RELATED APPLICATION

This application is based upon and claims the benefit of priority from the prior Japanese Patent Application No. 2009-38642, filed on Feb. 20, 2009; the entire contents of which are incorporated herein by reference.

### FIELD OF THE INVENTION

The invention relates to a nonvolatile semiconductor memory device and a manufacturing method for the same. More particularly, the invention relates to a nonvolatile semiconductor memory device having an improved structure of memory cell transistors, and to a manufacturing method for the same.

### DESCRIPTION OF THE BACKGROUND

An example of a nonvolatile semiconductor memory device is an electrically rewritable nonvolatile semiconductor memory using floating gate electrodes. A NAND-type flash memory is known as a typical nonvolatile semiconductor memory of such kind, and is increasingly in demand as a data storage device. In such a NAND-type flash memory, an inter-electrode insulating film is widely used in which an interfaces between upper and lower silicon layers are nitrided in order to reduce variations in characteristics of a memory cell transistor due to bird's beaks formed between the inter-electrode insulating film and the floating gate electrodes and between the inter-electrode insulating film and a control gate electrode (a NONON structure, for example).

Meanwhile, in a case where silicon nitride films exist in the inter-electrode insulating film as in the case of a NONON structure, there arises a problem that a threshold voltage of the memory cell transistor fluctuates due to a charge transfer to an adjacent memory cell transistor via the silicon nitride films. In order to prevent the above problem, Japanese Patent Application No. 2005-026590 proposes a structure not including a silicon nitride film in the inter-electrode insulating film on an element isolation insulating film.

However, another problem in turn arises that the aforementioned technique cannot be used in a memory cell transistor with the minimum processing dimension of 30 nm or less because a space large enough to place the inter-electrode film between the memory cell transistors cannot be secured in the memory cell transistor. The problem becomes more obvious as the memory cell transistors become higher in integration density.

### SUMMARY OF THE INVENTION

One aspect of the invention is to provide a nonvolatile semiconductor memory device that may comprise a semiconductor substrate, a tunnel insulating film being formed on the semiconductor substrate, a floating gate electrode being provided with a first floating gate electrode formed on the tunnel insulating film and a second floating gate electrode formed on the first floating gate electrode, a width of the second floating gate electrode being narrower in a channel-width direction than a width of the first floating gate electrode, element isolation insulating films being in contact with side surfaces of the first floating gate electrode and side surfaces of the tunnel insulating film, each of upper surfaces of the element isolation insulating films being on substantially the same level as upper surfaces of the first floating gate electrode, and each of lower portions of the element isolation insulating films being buried in the semiconductor substrate, an inter-electrode insulating film continuously covering an upper surfaces of the floating gate electrode, side surfaces in the channel-width direction of the floating gate electrode and the upper surface of the element isolation insulating films, and being higher in a nitrogen concentration in a boundary portion to the floating gate electrode than in boundary portions to the element isolation insulating films, and a control gate electrode being formed on the inter-electrode insulating film.

Another aspect of the invention is to provide a nonvolatile semiconductor memory device that may comprise a semiconductor substrate, a tunnel insulating film being formed on the semiconductor substrate, a floating gate electrode being provided with a first floating gate electrode formed on the tunnel insulating film and a second floating gate electrode formed on the first floating gate electrode, a width of the second floating gate electrode being narrower in a channel-width direction than a width of the first floating gate electrode, element isolation insulating films being in contact with side surfaces of the first floating gate electrode and side surfaces of the tunnel insulating film, each of upper surfaces of the element isolation insulating films being on substantially the same level as upper surfaces of the first floating gate electrode, and each of lower portions of the element isolation insulating films being buried in the semiconductor substrate, an inter-electrode insulating film continuously covering an upper surfaces of the floating gate electrode, side surfaces in the channel-width direction of the floating gate electrode and the upper surface of the element isolation insulating films, and being thicker in a thickness of a portion in contact with the floating gate electrode than in a thickness of portions in contact with the element isolation insulating films, and a control gate electrode being formed on the inter-electrode insulating film.

Another aspect of the invention is to provide a manufacturing method for a nonvolatile semiconductor memory device that may comprise forming a tunnel insulating film on a semiconductor substrate, forming a first conductive layer on the tunnel insulating film, forming a stopper film on the first conductive layer, forming an element isolating trench through selectively etching the stopper film, the first conductive layer, the tunnel insulating film and a portion of the semiconductor substrate, forming an insulating film on an entire surface including the element isolating trench, polishing and planarizing the insulating film to form a buried insulating film so as to be on substantially the same level as an upper surface of the stopper film, removing the stopper film and forming a gap on the first conductive layer, filling the gap with a second conductive layer, polishing and planarizing the second conductive layer so as to be on substantially the same level as upper surfaces of the buried insulating film, the second conductive layer composed together with the first conductive layer being assigned to a floating gate electrode, forming an element isolation insulating film, a first floating gate electrode with the side surface formed in contact with the element isolation insulating film, and a second floating gate electrode provided on the first floating gate electrode with the side surface formed in contact with the element isolation insulating film, the element isolation insulating film being formed, through etching an upper portion of the buried insulating film so as to remove a portion of the buried insulating film in a thickness direction of the floating gate electrode, making a width of the second floating gate electrode narrower in a channel-width direction than a width of the first floating gate electrode, forming an inter-electrode insulating film so as to continuously cover an upper surface of the floating gate electrode, side surfaces in the channel-width direction of the floating gate electrode and the upper surface of the element isolation insulating film, and forming a control gate electrode on the inter-electrode insulating film.

### BRIEF DESCRIPTION OF THE DRAWINGS

FIG. 1 is a plan view of a NAND-type flash memory according to embodiments of the invention.

FIG. 2 is an equivalent circuit diagram corresponding to FIG. 1 showing the NAND-type flash memory according to the embodiments of the invention.

FIG. 3A is a cross-sectional view taken along a line A1-A2 of FIG. 1 showing the NAND-type flash memory according to a first embodiment of the invention.

FIG. 3B is an enlarged view of a portion surrounded by a broken line of FIG. 3A.

FIGS. 4 through 11 are cross-sectional views taken along the line A1-A2 of FIG. 1 and showing manufacturing procedures of the NAND-type flash memory according to the first embodiment of the invention.

FIGS. 12 and 13 are cross-sectional views taken along the line A1-A2 of FIG. 1 and showing manufacturing procedures of the NAND-type flash memory according to a second embodiment of the invention.

FIGS. 14 and 15 are cross-sectional views taken along the line A1-A2 of FIG. 1 and showing manufacturing procedures of the NAND-type flash memory according to a third embodiment of the invention.

### DETAILED DESCRIPTION OF THE INVENTION

A nonvolatile semiconductor memory device according to embodiments of the invention will be described hereinafter with reference to the drawings by taking an electrically rewritable NAND-type flash memory as an example.

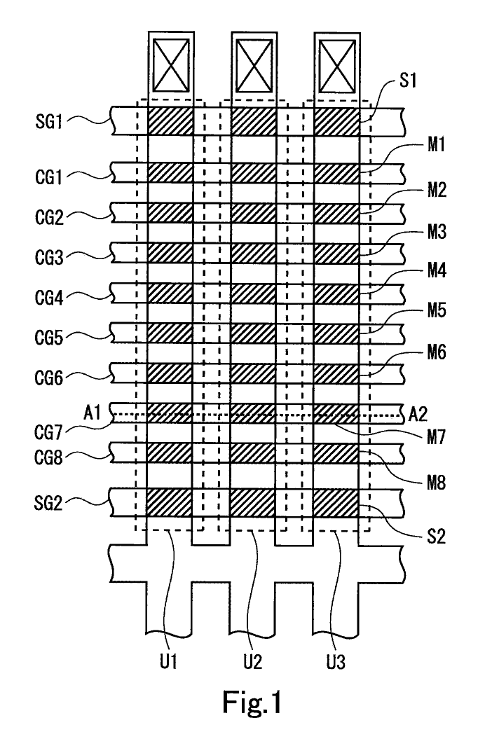

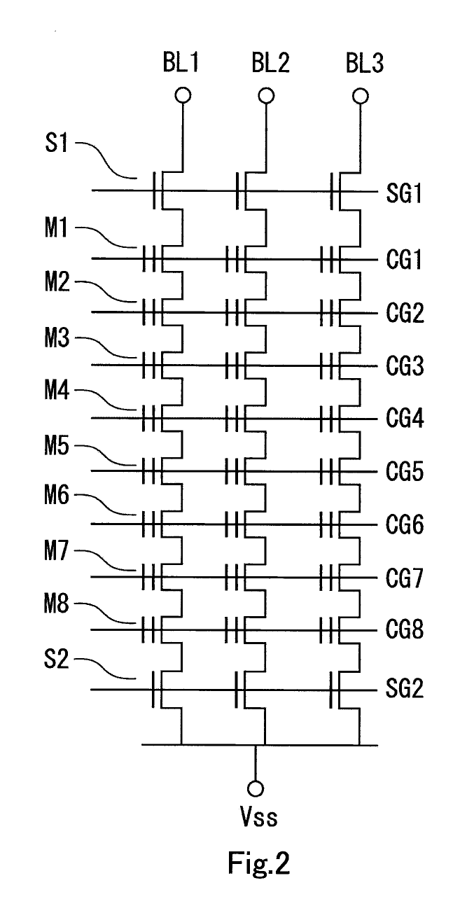

A nonvolatile semiconductor memory device according to a first embodiment of the invention and a manufacturing method of the same will be described with reference to FIGS. 1 through 11. FIG. 1 is a plan view schematically showing an overview configuration of a NAND-type flash memory according to the first embodiment. FIG. 2 is an equivalent circuit diagram of the configuration shown in FIG. 1.

As shown in FIGS. 1 and 2, the NAND-type flash memory includes a plurality of NAND cell units U1, U2, U3 (hereinafter, simply referred to as cell units) arranged in a column direction with an interval between each two adjacent cell units. Each of the cell units includes a plurality of select transistors S1, S2 and a plurality of memory cell transistors M1 to M8. The memory cell transistors M1 to M8 are arranged between the select transistors S1, S2 in a row direction and then connected to each other in series.

The select transistors S1, S2 of each of the cell units are connected respectively to select gate lines SG1, SG2 provided in the row direction. The memory cell transistors M1 to M8 are connected respectively to control gate lines (also, called word lines) CG1 to CG8 provided in the row direction. In addition, the select transistors S1 of the cell units U1, U2, U3 are connected respectively to bit lines BL1, BL2, BL3. Each of the select transistors S2 is connected to a power supply Vss from which a Vss source voltage is supplied. The description is given here of the case of eight memory cell transistors, as an example, but the number of memory cell transistors is not limited to eight. The description is given here of the case of three cell units, as an example, but the number of cell units is not limited to three.

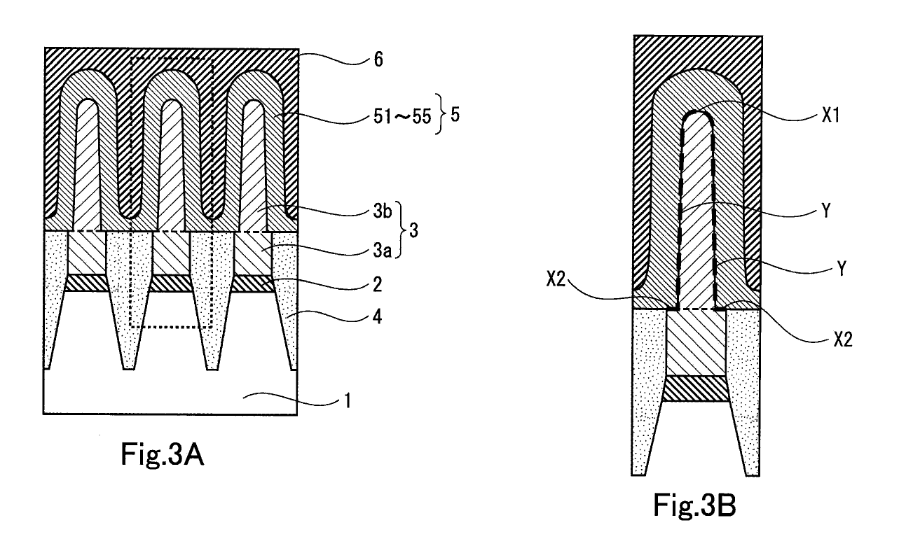

FIGS. 3A and 3B are cross-sectional views showing a memory cell transistor structure of the NAND-type flash memory according to the first embodiment of the invention. FIG. 3A is a cross sectional-view taken along a line A1-A2 of FIG. 1 and shows a cross-section in the word line direction (channel-width direction). FIG. 3B is an enlarged view showing a portion surrounded by a broken line of FIG. 3A.

As shown in FIG. 3A, each of the memory cell transistors M1 to M8 includes a silicon substrate 1, a floating gate electrode 3, an inter-electrode insulating film 5, a control gate electrode 6, and element isolation insulating films 4. The silicon substrate 1 is a semiconductor substrate. The floating gate electrode 3 is provided on a tunnel insulating film 2 formed on the silicon substrate 1. The inter-electrode insulating film 5 is provided on the floating gate electrode 3. The control gate electrode 6 is formed on the inter-electrode insulating film 5. Each of the element isolation insulating films 4 is formed between the floating gate electrode 3 and an adjacent floating gate electrode 3.

The silicon substrate 1 is a p-type silicon, for example. The tunnel insulating film 2 is formed of a silicon oxide film, a silicon oxynitride film or the like, for example, and is typically 1 to 15 nm in thickness.

The floating gate electrode 3 is formed of a silicon film containing P or the like, for example. The floating gate electrode 3 is arranged with predetermined interval to an adjacent floating gate electrode 3. The floating gate electrode 3 has a first floating gate electrode 3a and a second floating gate electrode 3b on the first floating gate electrode 3a. The width of the first floating gate electrode 3a in the channel-width direction is 30 nm or smaller, and the width of the second floating gate electrode 3b in the channel-width direction is smaller than that of the first floating gate electrode 3a by 4 to 10 nm.

As shown in FIG. 3B, the inter-electrode insulating film 5 continuously covers upper surfaces (X1, X2) and side surfaces (Y) of the floating gate electrode 3 and upper surfaces of the element isolation insulating films 4. Since the second floating gate electrode 3b has the smaller width in the channel-width direction than the first floating gate electrode 3a, a larger space is available for the inter-electrode insulating film 5 to be placed. The inter-electrode insulating film 5 is a NONON film obtained by sequentially stacking a silicon nitride film 51/a silicon oxide film 52/a silicon nitride film 53/a silicon oxide film 54/a silicon nitride film 55 in order from the lower layer of the structure, for example. As will be described later, a nitrogen concentration in the inter-electrode insulating film 5 is kept low so as to prevent a charge-transfer between adjacent memory cell transistors to each other.

Each of the element isolation insulating films 4 is provided so as to be in contact with side surfaces of the first floating gate electrode 3a and side surfaces of the tunnel insulating film 2. The element isolation insulating films 4 are not in contact with side surfaces of the second floating gate electrode 3b.

The control gate electrode 6 is formed for the inter-electrode insulating film 5. The control gate electrode 6 is formed of a silicon film containing P or the like, for example.

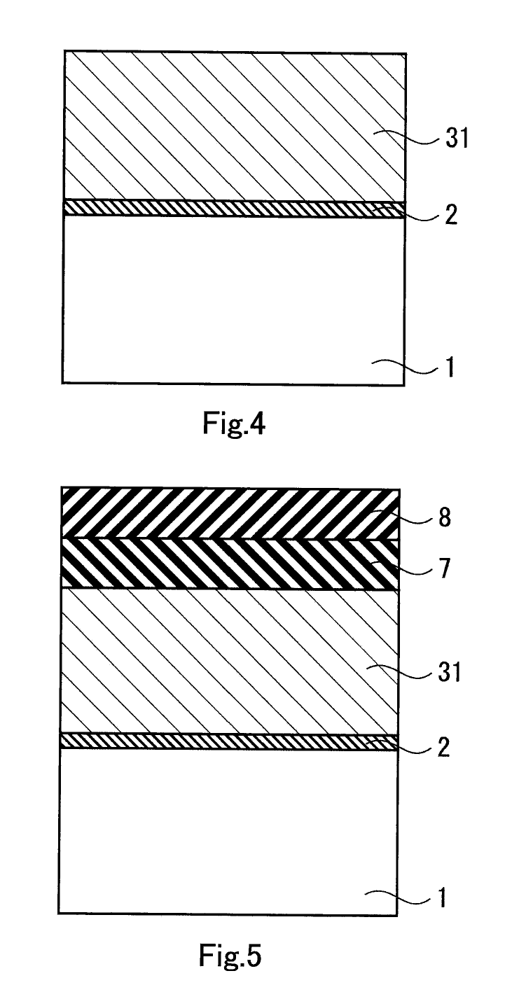

Hereinafter, the manufacturing method of the memory cell transistor of the NAND-type flash memory according to the first embodiment will be described with reference to FIGS. 4 though 11. FIGS. 4 through 11 show cross-sections in the word line direction (channel-width direction).

As shown in FIG. 4, the tunnel insulating film 2 having a film thickness of approximately 1 nm to 15 nm is formed on the silicon substrate 1 of a p-type or the silicon substrate 1 of an n-type in which a p-type well is formed. Next, a silicon film containing P to serve as a first conductive layer 31 having a film thickness of 10 nm to 200 nm is formed on the tunnel insulating film 2 by a chemical vapor deposition (CVD) method. The first conductive layer 31 is to serve as a part of the floating gate electrode 3. As shown in FIG. 5, a silicon nitride film 7 having a film thickness of 50 nm to 200 nm and a silicon oxide film 8 having a film thickness of 50 nm to 400 nm are sequentially formed on the first conductive layer 31 by a chemical vapor deposition method. The silicon nitride film 7 is to serve as a stopper during a chemical mechanical polishing (CMP) to be described later.

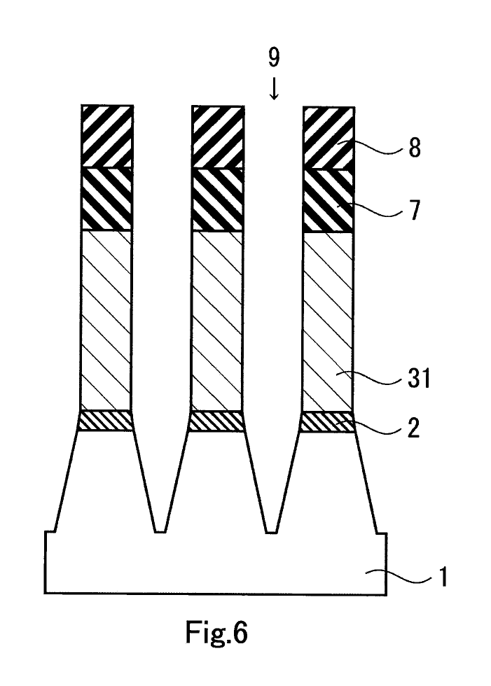

The silicon oxide film 8 is etched by using a photoresist (not shown) patterned as shown in FIG. 6, as a mask, and then, the photoresist is removed after the etching process. The silicon nitride film 7 is then etched by using the silicon oxide film 8 as a mask. Element isolating trenches 9 are formed by etching the first conductive layer 31, the tunnel insulating film 2, and a portion of the silicon substrate 1 with the mask of the silicon oxide film 8

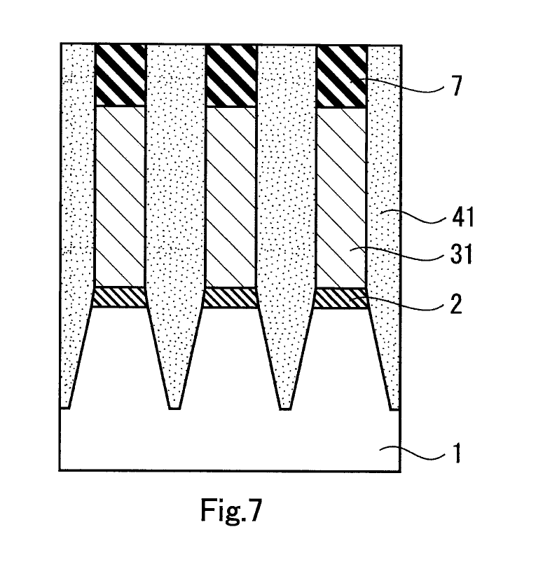

A buried insulating film 41 such as a silicon oxide film is formed to a thickness of 200 nm to 1500 nm to fill in the element isolating trench 9. The buried insulating film 41 is densified by a high temperature heating process in a nitrogen atmosphere or oxygen atmosphere. The buried insulating film 41 is planarized so as to be on the same level as the upper surface of the silicon nitride film 7 by CMP using the silicon nitride film 7 as a stopper. The structure shown in FIG. 7 is thus obtained.

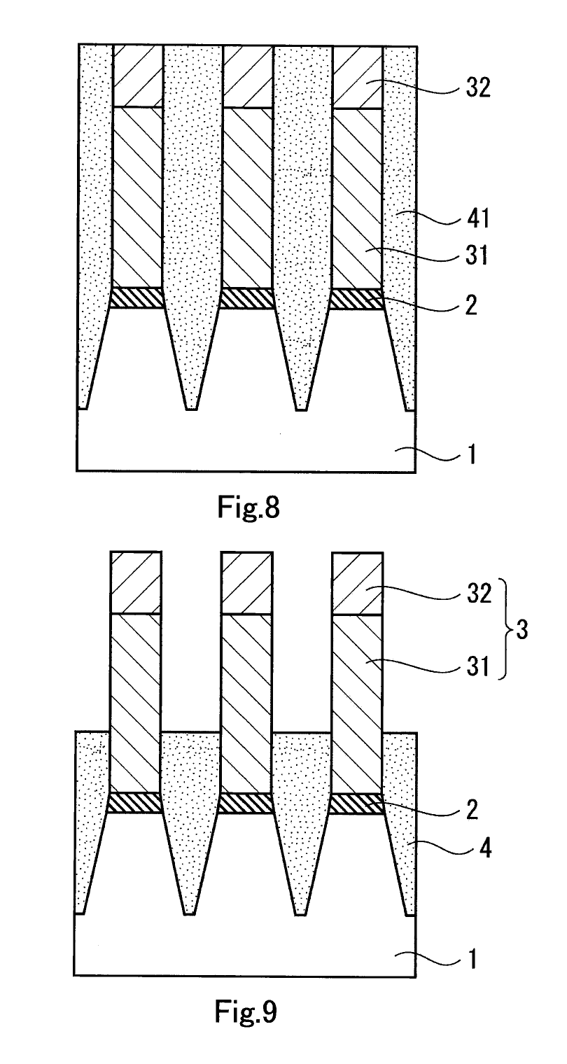

As shown in FIG. 8, the silicon nitride film 7 is etched away by using a method with which only the silicon nitride film 7 can be etched away. A gap is obtained by removing the silicon nitride film 7, a second conductive layer 32 that is to serve as a part of the floating gate electrode 3 is deposited on the gap by using an excellent step coverage method. The second conductive layer 32 is planarized by CMP so as to be on the same level as the upper surfaces of the buried insulating film 41. In the manner described above, the floating gate electrode 3 formed of the first conductive layer 31 and the second conductive layer 32 is obtained.

As shown in FIG. 9, the buried insulating film 41 is etched down to the level equivalent to the middle level of the floating gate electrode 3 in a film thickness direction by using a method with which the buried insulating film 41 can be etched at a certain selective ratio with respect to the floating gate electrode 3. The buried insulating film 41 thus obtained serves as the element isolation insulating films 4. The level of the upper surfaces of the element isolation insulating films 4 can be optionally determined within a range between the level equivalent to the upper surface of the floating gate electrode 3 and the level equivalent to the upper surface of the tunnel insulating film 2

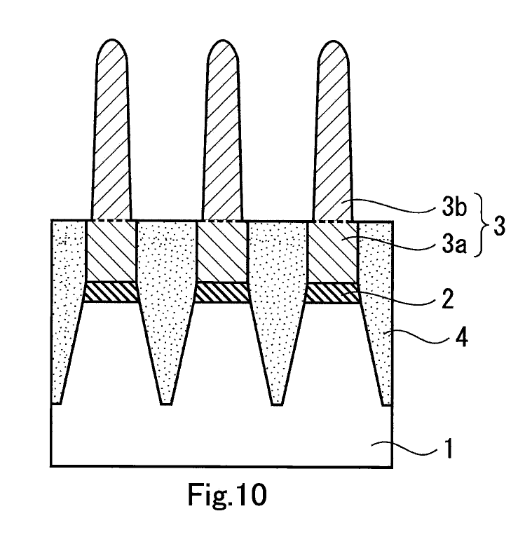

The floating gate electrode 3 is subjected to a slimming process by being exposed to a plasma atmosphere containing hydrogen. As a result, as shown in FIG. 10, the floating gate electrode 3 including the first floating gate electrode 3a and the second floating gate electrode 3b is formed, the first floating gate electrode 3a located directly on the tunnel insulating film 2, the second floating gate electrode 3b having a narrower width in the channel-width direction than that of the first floating gate electrode 3a. The slimming process increases a space between the second floating gate electrode 3b and an adjacent second floating gate electrode 3b to allow the inter-electrode insulating film 5 to be formed. Moreover, the second floating gate electrode 3b is arranged on the first floating gate electrode 3a without any positional misalignment. The second floating gate electrode 3b is arranged between extended planes of the side surfaces of the first floating gate electrode 3a. It is preferable that a plane at an equal distance from side surfaces of the second floating gate electrode 3b is almost coincident with that of the first floating gate electrode 3a after evenly slimming the side surfaces of the second floating gate electrode 3b. A slimming technique using a plasma containing halogen is not preferable because a residual halogen gas damages the tunnel insulating film 2. Note that, the first conductive layers 31 and the second conductive layer 32 are not distinguished in FIG. 10 and the drawings related to procedures after FIG. 10.

With the slimming technique in which the surfaces of the floating gate electrode 3 are subjected to plasma nitridation, the floating gate electrode 3 has to be nitrided by approximately 2 to 5 nm so as to be slimmed down. Moreover, the use of the slimming technique also nitrides the surfaces of the element isolation insulating films 4 to have a higher nitrogen concentration at the same time. Accordingly, the nitride layer higher in nitrogen concentration serves as a leak path to an adjacent memory cell transistor, hence causing a problem that charge retention characteristics of the memory cell transistor degrade considerably.

Meanwhile, the use of the slimming technique performed in a plasma atmosphere containing hydrogen leaves no residual impurities, and forms no charge conduction path. Accordingly, the use of the slimming technique performed in a plasma atmosphere containing hydrogen does not degrade the reliability of the memory cell transistor. A technique using inductively-coupled plasma (ICP) or a technique using microwave-excited plasma allows an efficient production of hydrogen radicals. For this reason, the ICP technique or the microwave-excited plasma technique is preferable because either one of the techniques allows not only the efficient etching of the floating gate electrode 3, but also the reduction in plasma damage.

Polysilicon etching can be performed with the plasma excitation pressure within a range of 50 mTorr to 2 Torr (6.7 Pa to 267 Pa). When the excitation pressure is low, the slimming process becomes anisotropic, and when the excitation pressure is high, the slimming process becomes isotropic. The pressure range of 500 mTorr to 2 Torr (67 Pa to 267 Pa) is preferable because the pressure range allows the efficient slimming and isotropic etching.

An atmosphere containing rare gases such as He, Ne, Ar, Kr and Xe, and hydrogen is more preferable because the atmosphere allows the efficient production of hydrogen radicals.

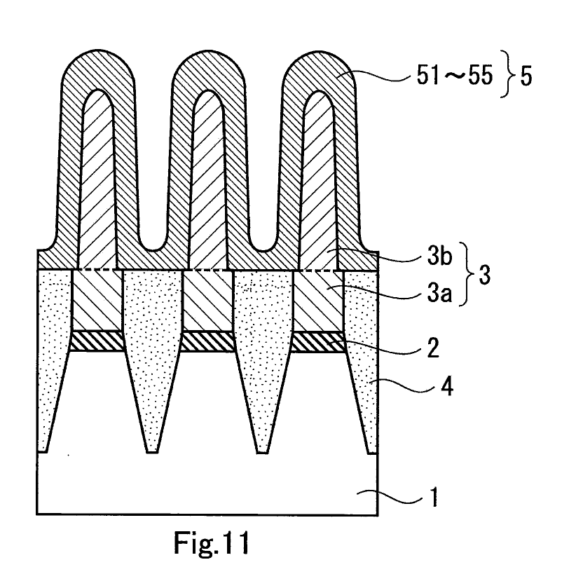

Next, as shown in FIG. 11, after the silicon nitride film 51 is formed on the upper surfaces and side surfaces of the floating gate electrode 3 as well as the upper surfaces of the element isolation insulating films 4 by the plasma nitridation method, the silicon oxide film 52 is formed by using an LPCVD (Low Pressure CVD) method or an ALD (Atomic Layer Deposition) method. Moreover, the silicon nitride film 53 and the silicon oxide film 54 are formed by using the LPCVD method or the ALD method. The silicon nitride film 55 is formed by nitriding a surface of the silicon oxide film 54 by a plasma nitridation method. Thus, the inter-electrode insulating film 5 (NONON film) provided with the silicon nitride film 51, the silicon oxide film 52, the silicon nitride film 53, the silicon oxide film 54, and the silicon nitride film 55 is formed.

The control gate electrode 6 is formed on the inter-electrode insulating film 5. As a result, the memory cell transistor of the NAND-type flash memory is completed as shown in FIGS. 3A and 3B.

According to the first embodiment, the floating gate electrode 3 is subjected to the slimming process. Thus, the space enough to allow the inter-electrode insulating film 5 to be formed can be secured between the floating gate electrode 3 and an adjacent second floating gate electrode 3. In addition, the inter-electrode insulating film 5 containing the silicon nitride films in the upper and lower layers of the inter-electrode insulating film 5, respectively can reduce variations in the memory cell transistor characteristics due to the bird's beaks. Moreover, the nitrogen concentration on the element isolation insulating films 4 is lower than that of a case where a plasma containing nitrogen is used for the slimming process, so that it is possible to suppress degradation in the charge retention characteristics due to the charge-transfer between the adjacent memory cell transistors to each other. Specifically, the nitrogen concentration on the element isolation insulating films 4 is not greater than 5E16 atoms/cm2 so as to prevent the occurrence of the charge-transfer between the adjacent cells. Moreover, the parasitic capacitance between the adjacent memory cell transistors to each other is reduced, thereby the high-speed writing and erasing being achieved.

The inter-electrode insulating film 5 is configured of a NONON film in the first embodiment, but the inter-electrode insulating film 5 may be configured of another insulating film involving insulating films having other compositions or involving other layered structures. The inter-electrode insulating film 5 including silicon nitride films as the upper and lower layers is preferable in order to prevent the bird's beaks.

In addition, the method to obtain the structure shown in FIG. 9 is not limited to the method shown in the first embodiment as long as the following structure can be obtained by the method. In the structure to be formed by the method, each of the element isolation insulating films 4 exists between the floating gate electrode 3 and an adjacent floating gate electrode 3, and the level of the upper surfaces of the element isolation insulating films 4 falls within a range between the level equivalent to the upper surfaces of the floating gate electrode 3 and the level equivalent to the upper surface of the tunnel insulating film 2. Although the floating gate electrode 3 is formed of a stacked structure of the first conductive layer 31 and the second conductive layer 32 in the first embodiment, the floating gate electrode 3 does not have to be necessarily formed of a stacked structure. The floating gate electrode 3 may include a single conductive layer. In this case, the process to planarize the second conductive layer 32 is no longer needed.

A second embodiment is different from the first embodiment in that a slimming process of the floating gate electrode 3 and a formation of a lowermost layer of the inter-electrode insulating film 5 are performed through exposure to a plasma atmosphere. Note that, since the other components of the second embodiment are the same as those of the first embodiment, the same reference numerals are used to denote the same components, and the descriptions of the same components are omitted.

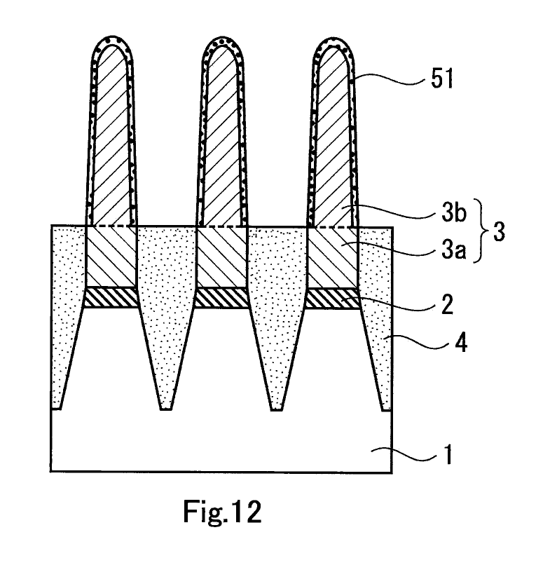

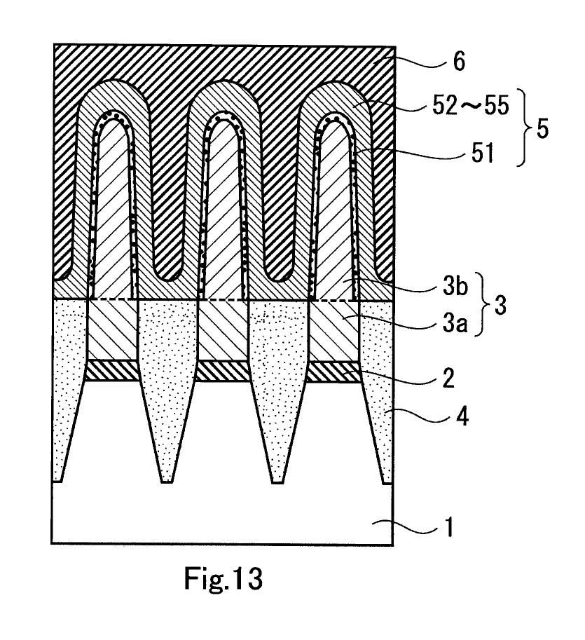

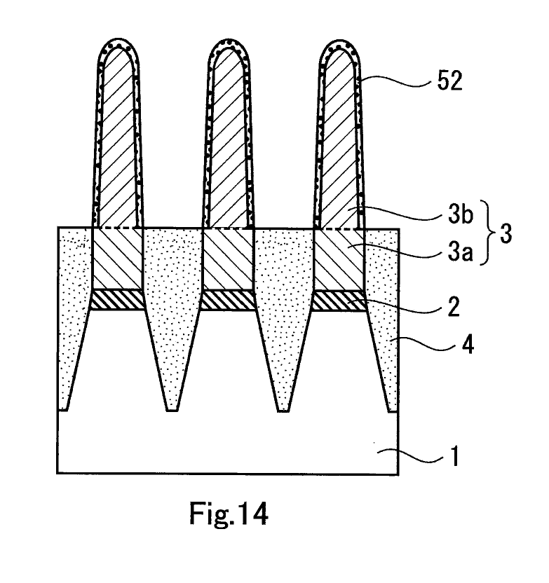

A manufacturing method of a memory cell transistor of the NAND-type flash memory according to the second embodiment will be described with reference to FIGS. 12 and 13. FIGS. 12 and 13 show cross-sections in the word line direction (channel-width direction).

Procedures in the manufacturing method according to the second embodiment until the procedure of forming the element isolation insulating films 4 shown in FIG. 9 are the same as the procedures of the manufacturing method according to the first embodiment.

As shown in FIG. 12, the floating gate electrode 3 is exposed to a plasma atmosphere containing hydrogen, and then subjected to a plasma nitridation through the exposure to the plasma atmosphere containing nitrogen and rare gases so that the floating gate electrode 3 is slimmed down. Further a silicon nitride film 51 is formed on the floating gate electrode 3. Normally, this process is performed as a single continuous process without removing the silicon substrate 1 from a plasma chamber.

The silicon nitride film 51 serves as the lowermost layer of the inter-electrode insulating film 5. The plasma nitridation to be performed at this time uses a selective nitridation condition that allows nitridation of the upper surfaces and side surfaces of the floating gate electrode 3, but that makes nitridation of the surfaces of the element isolation insulating films 4 difficult. Specific methods for the selective nitridation include an exposure to the plasma atmosphere containing rare gases, an increase in the plasma excitation pressure, an increase in a partial pressure of nitrogen, and the like. The selective nitridation only requires one of these conditions to be satisfied. Note that, while the pressure in the normal nitridation condition is 50 mTorr to 1 Torr (6.7 Pa to 133 Pa), approximately, the pressure is increased by three to ten times in the selective nitridation condition. With the selective nitridation described above, the nitrogen concentration on the element isolation insulating films 4 can be lowered. Specifically, the nitride concentration on the element isolation insulating films 4 becomes 5E16 atoms/cm2 or less at which no charge-transfer between adjacent memory cell transistors to each other occurs.

The floating gate electrode 3 is subjected to the slimming process by the exposure to the plasma atmosphere containing hydrogen. Accordingly, the floating gate electrode 3 is formed, that includes the first floating gate electrode 3a deposited directly on the tunnel insulating film 2, and the second floating gate electrode 3b having a narrower width in the channel-width direction than that of the first floating gate electrode 3a. Accordingly, a space to form the inter-electrode insulating film 5 between the floating gate electrode 3 and an adjacent floating gate electrode 3 is widened.

As shown in FIG. 13, the silicon oxide film 52, the silicon nitride film 53, the silicon oxide film 54, and the silicon nitride film 55 are formed on the silicon nitride film 51. The inter-electrode insulating film 5 (NONON film) configured of the silicon nitride film 51 through the silicon nitride film 55 is thus formed.

Thereafter, the memory cell transistor of the NAND-type flash memory is completed through the same procedures of forming the control gate electrode 6 as the procedures in the first embodiment.

According to the aforementioned manufacturing method of the second embodiment, a nitrogen concentration on the element isolation insulating films 4 can be lowered than that of the silicon nitride film 51. Specifically, the nitrogen concentration at the boundary between the inter-electrode insulating film 5 and the floating gate electrode 3 is higher than the nitrogen concentration at the boundary between the inter-electrode insulating film 5 and the element isolation insulating films 4. Furthermore, the manufacturing method of the second embodiment requires less number of processes than a conventional technique does since the slimming process of the floating gate electrode 3 and the formation of the silicon nitride film 51 can be performed as the single continuous process.

In addition, the description is given of the case where the inter-electrode insulating film 5 is configured of the NONON film, but an insulating film configuration on the silicon nitride film 51 does not matter as long as the lowermost layer of the inter-electrode insulating film 5 to be formed directly on the floating gate electrode 3 is the silicon nitride film 51. For example, a structure formed of a silicon nitride film/a silicon oxide film/an alumina film/a silicon oxide film/a silicon nitride film (NOAON film) may be employed alternatively as the inter-electrode insulating film.

A third embodiment is different from the second embodiment in that a slimming process of the floating gate electrode 3 and a formation of a lowermost layer of the inter-electrode insulating film 5 are performed by a radical oxidation. Furthermore, the third embodiment is different from the second embodiment in that the lowermost layer of the inter-electrode insulating film 5 is not a silicon nitride film, but a silicon oxide film. Note that, since the other components of the third embodiment are the same as those of the first and second embodiments, the same reference numerals are used to denote the same components, and the descriptions of the same components are omitted.

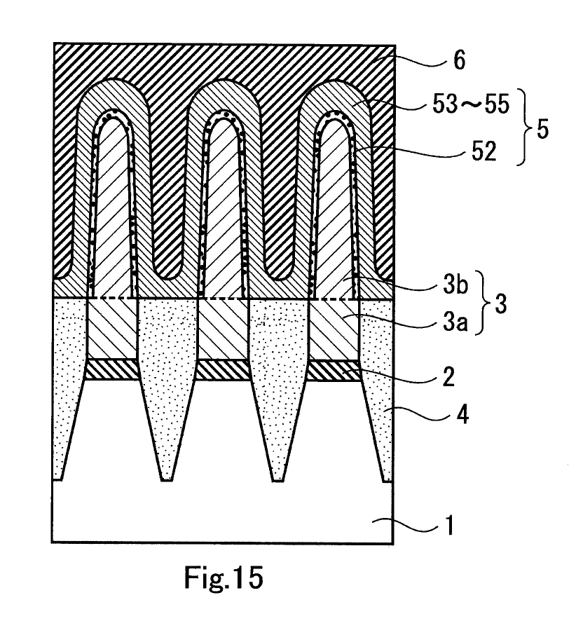

A manufacturing method of a memory cell transistor of the NAND-type flash memory according to the third embodiment will be described with reference to FIGS. 14 and 15. FIGS. 14 and 15 show cross-sections in the word line direction (channel-width direction).

Procedures of the manufacturing method according to the third embodiment until the procedures of forming the element isolation insulating films 4 shown in FIG. 9 are the same as those of the manufacturing methods according to the first and second embodiments.

As shown in FIG. 14, the radical oxidation is performed in an atmosphere containing oxygen and rare gases such as He, Ar, and Kr under a pressure of 50 mTorr to 2 Torr (6.7 Pa to 267 Pa) using a high-density plasma. A silicon oxide film 52 is formed on the upper surfaces and side surfaces of the floating gate electrode 3 by the radical oxidation under the aforementioned conditions. At this time, since each of the element isolation insulating films 4 essentially contains the silicon oxide film, the silicon oxide film is not formed on the element isolation insulating films 4. The silicon oxide film 52 serves as the lowermost layer of the inter-electrode insulating film 5

The floating gate electrode 3 is subjected to the slimming process by the radical oxidation. Thus, the floating gate electrode 3 is formed, that includes the first floating gate electrode 3a deposited directly on the tunnel insulating film 2, and the second floating gate electrode 3b having a narrower width in the channel-width direction than that of the first floating gate electrode 3a.

If the silicon oxide film 52 is formed by a thermal oxidation method on the floating gate electrode 3 made of a silicon film, there arises a problem that the film thickness of the silicon oxide film 52 does not become uniform among the memory cell transistors because of an oxidation rate difference due to a difference in plane orientation of the silicon. However, the use of the aforementioned radical oxidation allows the oxidation of the floating gate electrode 3 without a plane orientation dependence, and thus prevents a variation in the thickness of the inter-electrode insulating film 5 among the memory cell transistors to a large extent.

Here, the slimming process of the floating gate electrode 3 and the formation of the silicon oxide film 52 are performed by the radical oxidation, but the silicon oxide film 52 may be formed by performing the radical oxidation after the floating gate electrode 3 is subjected to the slimming process by the exposure to the plasma atmosphere containing hydrogen as shown in the first embodiment. The atmosphere at the time of the radical oxidation may not contain the rare gases, or may contain hydrogen.

As shown in FIG. 15, the silicon nitride film 53, the silicon oxide film 54, and the silicon nitride film 55 are formed on the silicon oxide film 52. The inter-electrode insulating film 5 (ONON film) thus configured of the silicon oxide film 52 through the silicon nitride film 55 is formed. The film thickness of the inter-electrode insulating film 5 formed in the aforementioned manner is thinner on the element isolation insulating films 4 than on the upper surface and side surfaces of the floating gate electrode 3. In other words, the film thickness of a portion of the inter-electrode insulating film 5 in contact with the floating gate electrode 3 is thicker than the film thickness of portions of the inter-electrode insulating film 5 in contact with the element isolation insulating films 4. This is because the silicon oxide film 52 is not formed on the element isolation insulating films 4

Thereafter, the memory cell transistor of the NAND-type flash memory is completed through the same procedures of forming the control gate electrode 6 as those of the first embodiment.

With the manufacturing method according to the third embodiment, the width of the first floating gate electrode 3a is smaller than the width of the second floating gate electrode 3b, so that a space to form the inter-electrode insulating film 5 between the floating gate electrodes 3 and an adjacent floating gate electrode 3 is widened. Moreover, since no silicon nitride film exists on the element isolation insulating film 4, degradation in the charge retention characteristics due to a charge-transfer between the adjacent memory cell transistors to each other can be suppressed. In addition, the parasitic capacitance between the adjacent memory cell transistors to each other can be reduced. Thus, it is made possible to perform high-speed writing and erasing.

The use of the manufacturing method according to the third embodiment requires less number of processes than a conventional technique does, because the slimming process of the floating gate electrode 3 and the formation of the silicon oxide film 52 can be performed as a single continuous process in the radical oxidation process.

In addition, in the third embodiment, the silicon nitride films only exist in the middle and upper layers of the inter-electrode insulating film 5, respectively, and no silicon nitride film exists in the lower layer. Accordingly, for the reduction of a variation in the memory cell transistor characteristics due to the bird's beaks, it is preferable to avoid a procedure involving a large oxidizing power after the formation of the inter-electrode insulating film 5

Moreover, the description is given of the case where the inter-electrode insulating film 5 is configured as the ONON film, but the film type on the silicon oxide film 52 does not matter as long as the lowermost layer of the inter-electrode insulating film 5 to be formed directly on the floating gate electrode 3 is the silicon oxide film 52. For example, a structure formed of a silicon oxide film/an alumina film/a silicon oxide film/a silicon nitride film (OAON film) may be employed as the inter-electrode insulating film.

The invention is not limited to the aforementioned embodiments. The invention can be performed in various modified forms without departing from the sprit of the invention.

What is claimed is:

1. A nonvolatile semiconductor memory device including a plurality of memory cell transistors, each of the memory cell transistors comprising:
a semiconductor substrate;
a tunnel insulating film being formed on the semiconductor substrate;
a floating gate electrode being provided with a first floating gate electrode formed on the tunnel insulating film and a second floating gate electrode formed on the first floating gate electrode, a width of the second floating gate electrode being narrower in a channel-width direction than a width of the first floating gate electrode;
element isolation insulating films being in contact with side surfaces of the first floating gate electrode and side surfaces of the tunnel insulating film, each of upper surfaces of the element isolation insulating films being on substantially the same level as upper surfaces of the first floating gate electrode, and each of lower portions of the element isolation insulating films being buried in the semiconductor substrate;
an inter-electrode insulating film continuously covering an upper surfaces of the floating gate electrode, side surfaces in the channel-width direction of the floating gate electrode and the upper surface of the element isolation insulating films, and being higher in a nitrogen concentration in a boundary portion to the floating gate electrode than in boundary portions to the element isolation insulating films; and
a control gate electrode being formed on the inter-electrode insulating film.

2. The device according to claim 1, wherein the inter-electrode insulating film has a silicon nitride film.

3. The device according to claim 1, wherein the inter-electrode insulating film is a layered insulating film including a silicon nitride film as a lowermost layer and a silicon nitride film as an uppermost layer.

4. The device according to claim 3, wherein the inter-electrode insulating film has an alumina film.

5. The device according to claim 1, wherein the second floating gate electrode is arranged between extended planes of the side surfaces of the first floating gate electrode.

6. A nonvolatile semiconductor memory device including a plurality of memory cells having memory cell transistors respectively, each of the memory cell transistors comprising:
a semiconductor substrate;
a tunnel insulating film being formed on the semiconductor substrate;
a floating gate electrode being provided with a first floating gate electrode formed on the tunnel insulating film and a second floating gate electrode formed on the first floating gate electrode, a width of the second floating gate electrode being narrower in a channel-width direction than a width of the first floating gate electrode;
element isolation insulating films being in contact with side surfaces of the first floating gate electrode and side surfaces of the tunnel insulating film, each of upper surfaces of the element isolation insulating films being on substantially the same level as upper surfaces of the first floating gate electrode, and each of lower portions of the element isolation insulating films being buried in the semiconductor substrate;
an inter-electrode insulating film continuously covering an upper surfaces of the floating gate electrode, side surfaces in the channel-width direction of the floating gate electrode and the upper surface of the element isolation insulating films, and being thicker in a thickness of a portion in contact with the floating gate electrode than in a thickness of portions in contact with the element isolation insulating films; and
a control gate electrode being formed on the inter-electrode insulating film.

7. The device according to claim 6, wherein the inter-electrode insulating film has a silicon oxide film.

8. The device according to claim 6, wherein the inter-electrode insulating film is a layered insulating film including a silicon oxide film as a lowermost layer.

9. The device according to claim 8, wherein the inter-electrode insulating film has an alumina film.

10. The device according to claim 6, wherein the second floating gate electrode is arranged between extended planes of the side surfaces of the first floating gate electrode.

11. A manufacturing method for a nonvolatile semiconductor memory device comprising:
forming a tunnel insulating film on a semiconductor substrate;
forming a first conductive layer on the tunnel insulating film;
forming a stopper film on the first conductive layer;
forming an element isolating trench through selectively etching the stopper film, the first conductive layer, the tunnel insulating film and a portion of the semiconductor substrate;
forming an insulating film on an entire surface including the element isolating trench;
polishing and planarizing the insulating film to form a buried insulating film so as to be on substantially the same level as an upper surface of the stopper film;
removing the stopper film and forming a gap on the first conductive layer;
filling the gap with a second conductive layer;
polishing and planarizing the second conductive layer so as to be on substantially the same level as upper surfaces of the buried insulating film, the second conductive layer composed together with the first conductive layer being assigned to a floating gate electrode;
forming an element isolation insulating film, a first floating gate electrode with the side surface formed in contact with the element isolation insulating film, and a second floating gate electrode provided on the first floating gate electrode with the side surface formed in contact with the element isolation insulating film, the element isolation insulating film being formed, through etching an upper portion of the buried insulating film so as to remove a portion of the buried insulating film in a thickness direction of the floating gate electrode;
making a width of the second floating gate electrode narrower in a channel-width direction than a width of the first floating gate electrode;
forming an inter-electrode insulating film so as to continuously cover an upper surface of the floating gate electrode, side surfaces in the channel-width direction of the floating gate electrode and the upper surface of the element isolation insulating film; and
forming a control gate electrode on the inter-electrode insulating film.

12. The manufacturing method according to claim 11, wherein the inter-electrode insulating film is a layered insulating film including a silicon nitride film as a lowermost layer.

13. The manufacturing method according to claim 11, wherein making the width of the second floating gate electrode narrower and forming the lowermost layer of the inter-electrode insulating film are successively and continuously performed.

14. The manufacturing method according to claim 13, wherein the inter-electrode insulating film includes a silicon nitride as a lowermost layer.

15. The manufacturing method according to claim 14, wherein the silicon nitride as the lowermost layer is formed by a plasma nitridation.

16. The manufacturing method according to claim 15, wherein the plasma nitridation is performed by an exposure to the plasma atmosphere containing rare gases.

17. The manufacturing method according to claim 15, wherein the plasma nitridation is performed in the excited plasma pressure of 150 mTorr to 10 Torr.
